(19) United States
(12) Patent Application Publication
(10) Pub. No.: US 2014/0244053 A1
(43) Pub. Date: Aug. 28, 2014

(54) Apparatus and Method for Connecting Electrical Units

(71) Applicant: AURA SYSTEMS, INC., El Segundo, CA (US)

(72) Inventors: Si Ryong Yu, Gyeonggi-do (KR); Zvi Kurtzman, Sandy Springs, GA (US)

(73) Assignee: Aura Systems, Inc., El Segundo, CA (US)

(21) Appl. No.: 13/781,749

(22) Filed: Feb. 28, 2013

(51) Int. Cl. H02J 4/00; G06F 1/26; H05K 13/00

(52) U.S. Cl. CPC H02J 4/00; H05K 13/00; G06F 1/26
USPC 700/286; 29/593; 307/130

(57) ABSTRACT

An apparatus and method for connecting electrical units including determining that a first electrical connection is mated with a first electrical receptacle at a first point of connection; determining that a second electrical connection is mated with a second electrical receptacle at a second point of connection, wherein the first second point of connection and the second point of connection are at opposite ends of an electrical cable; initiating delivery of voltage through the electrical cable; monitoring the voltage level of a source that outputs the delivery of the voltage; and comparing the voltage level of the source with a predetermined value to generate a comparison value.

### FIELD

This disclosure relates generally to apparatus and methods for electrical connections. More particularly, the disclosure relates to high voltage electrical connections.

### BACKGROUND

Electrical connections between two electrical units are pan of many electrical systems. Typically, there are two points of connection. The first point of connection is where an electrical cable is connected to a first electrical unit. The second point of connection is where the same electrical cable is connected to the second electrical unit. With this arrangement, the electrical cable electrically connects the first electrical unit with the second electrical unit. When the two points of connection are mated properly, there is no concern. However, when the electrical connections involve high voltages, there is a safety concern that the points of connection may not be mated properly, that the electrical cable may be damaged, or an inadvertent disconnect on one of the two points of connections may present an electrical hazard. And, in some cases, the electrical hazard may be the cause of a fatal accident. Thus, it is desirable to implement safety features on the electrical cable and/or the points of connection.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

Disclosed is an apparatus and method for high voltage electrical connections. According to one aspect, a method for connecting electrical units, including determining that a first electrical connection is mated with a first electrical receptacle at a first point of connection; determining that a second electrical connection is mated with a second electrical receptacle at a second point of connection, wherein the first second point of connection and the second point of connection are at opposite ends of an electrical cable; initiating delivery of voltage through the electrical cable; monitoring the voltage level of a source that outputs the delivery of the voltage; and comparing the voltage level of the source with a predetermined value to generate a comparison value.

According to another aspect, a device comprising a processor and a memory, the memory containing program code executable by the processor for performing the following: determining that a first electrical connection is mated with a first electrical receptacle at a first point of connection; determining that a second electrical connection is mated with a second electrical receptacle at a second point of connection, wherein the first second point of connection and the second point of connection are at opposite ends of an electrical cable; initiating delivery of voltage through the electrical cable; monitoring the voltage level of a source that outputs the delivery of the voltage; and comparing the voltage level of the source with a predetermined value to generate a comparison value.

According to yet another aspect, a computer program product embodied on a non-transitor computer-readable storage medium and comprising code that, when executed, causes a computer to perform the following: determining that a first electrical connection is mated with a first electrical receptacle at a first point of connection; determining that a second electrical connection is mated with a second electrical receptacle at a second point of connection, wherein the first second point of connection and the second point of connection are at opposite ends of an electrical cable; initiating delivery of voltage through the electrical cable; monitoring the voltage level of a source that outputs the delivery of the voltage; and comparing the voltage level of the source with a predetermined value to generate a comparison value.

According to yet another aspect, a system for connecting electrical units, including: a first sensor for determining that a first electrical connection is mated with a first electrical receptacle at a first point of connection a second sensor for determining that a second electrical connection is mated with a second electrical receptacle at a second point of connection wherein the first second point of connection and the second point of connection are at opposite ends of an electrical cable; an electrical control unit (ECU) for initiating delivery of voltage through the electrical cable based on a first measurement from the first sensor and a second measurement form the second sensor; and a digital signal processor (DSP) coupled to the ECU for monitoring the voltage level of a source that outputs the delivery of the voltage, and for comparing the voltage level at the source with a predetermined value to generate a comparison value.

Advantages of the present disclosure may include reducing or minimizing electrical accidents relating to a high voltage electrical connection.

It is understood that other aspects will become readily apparent to those skilled in the art from the following detailed description, wherein it is shown and described various aspects by way of illustration. The drawings and detailed description are to be regarded as illustrative in nature and not as restrictive.

### BRIEF DESCRIPTION OF THE DRAWINGS

FIG. 1 illustrates an example of a tractor and trailer system with an electrical cable connecting the tractor and the trailer.

FIG. 2 illustrates an example of a cable connecting end.

FIG. 3 illustrates an example interior view of the chassis connecting section and example interior view of the cable connecting section.

FIG. 4 illustrates an example of two components of a proximity sensor

FIG. 5 illustrates are example flow diagram for connecting electrical units.

FIG. 6 illustrates n example of a device comprising a processor in communication with a memory for executing connecting electrical units.

### DETAILED DESCRIPTION

The detailed description set forth below in connection with the appended drawings is intended as a description of various aspects of the present disclosure and is not intended to represent the only aspects in which the present disclosure may be practiced. Each aspect described in this disclosure is provided merely as an example or illustration of the present disclosure, and should not necessarily be construed as preferred or advantageous over other aspects. The detailed description includes specific details for the purpose of providing a thorough understanding of the present disclosure. However, it will be apparent to those skilled in the art that the present disclosure may be practiced without these specific details. In some instances, well-known structures and devices are shown in block diagram form in order to avoid obscuring the concepts of the present disclosure. Acronyms and other descriptive terminology may be used merely for convenience and clarity and are not intended to limit the scope of the present disclosure.

While for purposes of simplicity of explanation, the methodologies are shown and described as a series of acts, it is to be understood and appreciated that the methodologies are not limited by the order of acts, as some acts may, in accordance with one or more aspects, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with one or more aspects.

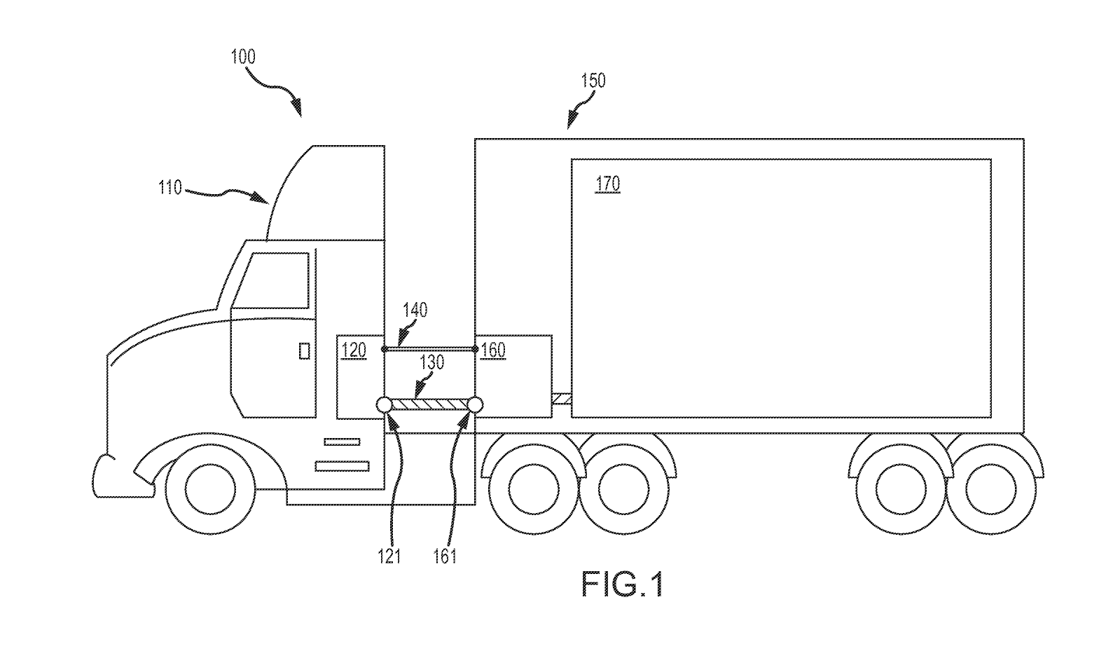

FIG. 1 illustrates an example of a tractor and trailer system 100 with an electrical cable 130 connecting the tractor 110 and the trailer 150. As shown in the example, in FIG. 1, the electrical cable connects an electrical control unit (ECU) 120 with an inverter unit 160. In this example, the ECU 120 is located in the tractor 110 and the inverter unit 160 is located in the trailer 150. A first point of connection 121 of the electrical cable 130 is the interface with the ECU 120, A second point of connection 161 of the electrical cable 130 is the interface with the inverter unit 160.

In one example, the trailer 150 includes an electrical load 170 (e.g., a refrigeration device) that requires alternating current (AC) voltage to operate. In one aspect, the AC voltage is supplied to the electrical load 170 by the inverter unit 160. Although the output of the inverter unit 160 is AC voltage, the input electrical source to the inverter unit 160 is a direct current (DC) voltage supplied through the ECU 120. In one example, one or more generators and/or one or more DC batteries are connected to the ECU 120 to supply the DC voltage. Thus, in one example, the ECU 120 may output DC voltages while the tractor engine is on and supplying the ECU or a battery is supplying the ECU 120 while the tractor engine is off. In one example, the one or more generators is the tractor engine. In one example, the ECU 120 supplies 750 Volts DC to the inverter unit 160 through the electrical cable 130. In one example, the output of the inverter unit 160 to the electrical load 170 is 480 Volts AC. In one example, the output of the inverter unit 160 is a three phase AC waveform.

In one aspect, a communication line 140 is coupled between the tractor 110 and the trailer 150. The communication line 140 allows information exchange between the tractor 110 and the trailer 150. In one example, the tractor 110 includes a first digital signal processor (DSP) 115 (not shown), and the trailer 150 includes a second digital signal processor (DSP) 155 (not shown). In one example, the communication line 140 connects the first DSP 115 with the second DSP 155 to allow the two DSPs to communication with one another. In one example, the first DSP 115 is coupled to the ECU 120. In one example, the second DSP 155 is coupled to the inverter 160. In one example, the communication line 140 is part of the electrical cable 130.

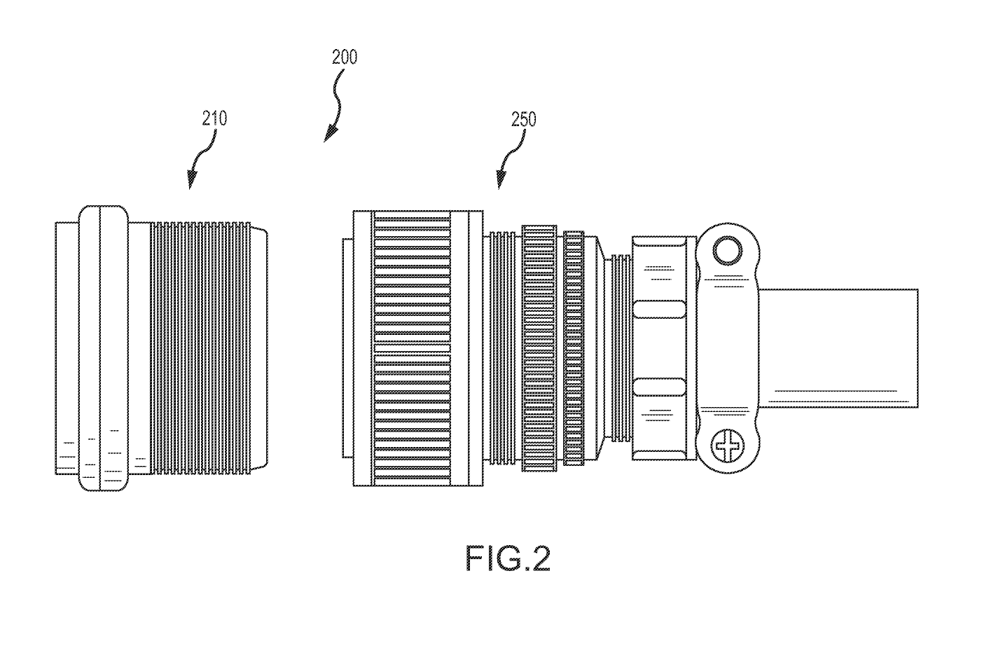

FIG. 2 illustrates an example of a cable connecting end 200. In one aspect, the electrical cable 130 includes two cable connecting ends 200. For example, one of the cable connecting end 200 is located at one end of the electrical cable 130 while the other cable connecting end 200 is located at the opposite end of the electrical cable 130. In one example, the cable connecting end 200 includes a cable connecting section 250. The cable connecting section 250 mates to a chassis connecting section 210 to allow electrical connection. In each system, there are two cable connection sections 250 and two chassis connection sections 210. In one example, a chassis connecting section 210 is part of the tractor 110, located at the first point of connection 121. For the connection of the electrical cable 130 with the trailer 150, a chassis connecting section 210 is part of the trailer 150, located at the second point of connection 161. Although the example herein illustrates an electrical connection between a tractor and a trailer, one skilled in the art would understand that the scope and spirit of the present disclosure may include an electrical connection between any two electrical components and need not be limited to a tractor and trailer system.

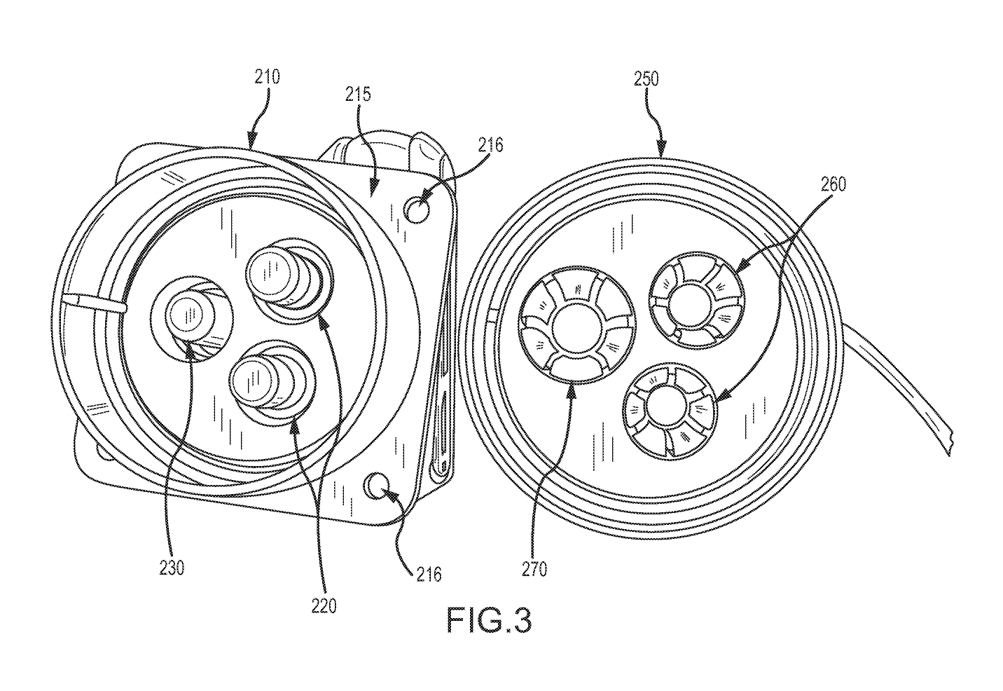

FIG. 3 illustrates an example interior view of the chassis connecting section 210 and an example interior view of the cable connecting section 250. As shown in FIG. 3, the chassis connecting section 210 includes a mounting board 215 and one or more mounting holes 216 for mounting the chassis connecting section 210, for example, to a component of the tractor 110 or a component of the trailer 150.

In one example, the interior of the chassis connecting section 210 includes two electrical connections 720 and one sensor connection 230. In one example, the interior of the cable connecting section 250 includes two electrical receptacles 260 and one sensor receptacle 270. The two electrical connections 220 mate with the two electrical receptacles 260, and the sensor connection 230 mates with the sensor receptacle 270. When the electrical connections 220 are properly mated with the electrical receptacles 260 at both the first point of connection 121 and the second point of connection 161, an electrical path between the tractor 110 and the trailer 150 is formed.

One example of determining whether there is proper mating of the electrical connections 220 with the electrical receptacles 260 is based on the coupling of the sensor connection 230 and the sensor receptacle 270. The sensor connection 230 and the sensor receptacle 270 form a sensor. In one example, the sensor is a proximity sensor.

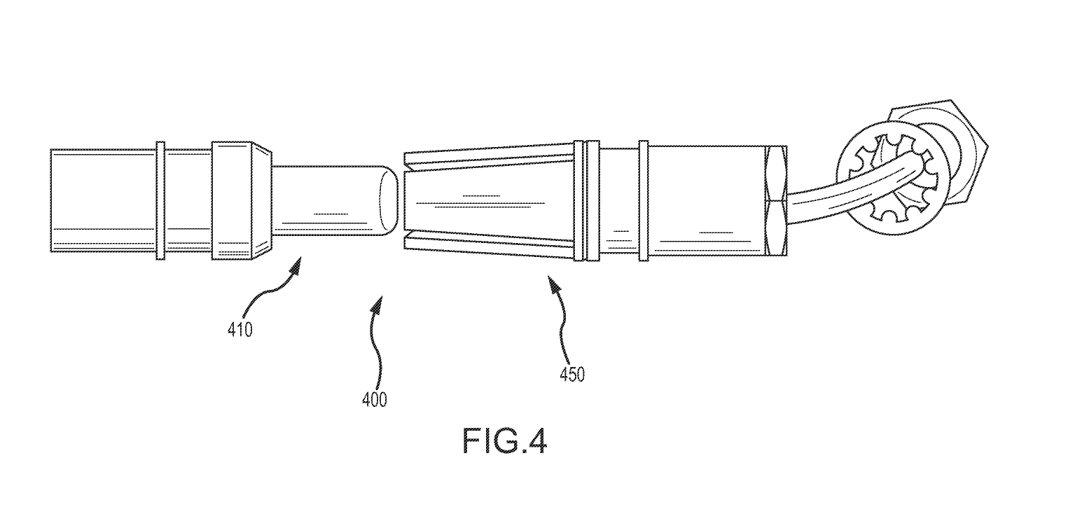

FIG. 4 illustrates an example of two components of a proximity sensor 400. As shown in FIG. 4, the proximity sensor includes two components: a probe 410 and a probe receptacle 450. In one aspect, when the probe 410 is within a predetermined proximity to the probe receptacle, 450, the proximity probe 400 will determine that there is proper mating of the electrical connections 220 with the electrical receptacles 260. In one example, having proper mating means that there is adequate threading between the electrical connections 220 and the electrical receptacles 260. Once there is proper mating, the ECU 120 will be allowed to provide DC voltage to the inverter 160.

Other examples of the sensor may include, but is not limited to, magnetic Sensor, electromagnetic sensor, optoelectronic sensor, infrared sensor, radio frequency (RF) sensor, piezoelectric sensor, etc. In one example, the electrical connection 220 and the electrical receptacle 260 are locked to each other by a mechanical locking device and their mating (whether proper or not) is determined by a sensor. In one example, the mechanical locking device may include mechanical threads and groves that interact with each other to form a seal. One skilled in the art would understand that any sensor that can be used to determine whether there is proper mating between the chassis connection section 210 and the cable connection section 250 is within the scope and spirit of the present disclosure.

In one aspect, once the sensor located at or near the first point of connection 121 determines that there is proper mating at the first point of connection 121, the information is transmitted to the first DSP 115. And, once the other sensor located at or near the second point of connection 161 determines that there is proper mating at the second point of connection 161, the information is transmitted to the second DSP 155. Using the communication line 140, the second DSP 155 sends a signal to the first DSP 115 to indicate that there is proper mating at the second point of connection 161. Once the first DSP 115 determines that there is proper mating at the first point of connection 121 and receives information that there is proper mating at the second point of connection 161, the first DSP 115 triggers the ECU 120 to output its DC voltage through the electrical path established between the ECU 120 and the inverter 160 through the electrical cable 130 (i.e., though the electrical path established between the tractor 110 and the trailer 150). Although the example illustrates that the first DSP 115 is used to trigger the ECU, another DSP (e.g., second DSP 155) that has information that the connections at both the first point of connection 121 and the second point of connection 161 are properly mated ma be used to trigger the ECU 120 to start and/or continue delivery of DC voltage to the inverter 160.

In one aspect, during delivery of the DC voltages from the ECU 120 to the inverter 160, one of the DSPs 115, 155 determines that there is either a disconnection at the first point of connection 121 or the second point of connection 161, or the electrical cable 130 is damaged (c.a., a cut or nick on the electrical cable), then the first DSP 115 may instruct the ECU 120 to stop delivery of DC voltages to the inverter 160. In one example, DC power levels of the ECU 120 are monitored to determine whether there is either a disconnection at the first point of connection 121 or the second point of connection 161, or the electrical cable 130 is damaged. For example if the delivery from the ECU 120 is expected at 750 Volts DC and there is a determination that the voltage has deviated from the 750 Volts DC value by a predetermined delta value, then the first DSP 115 would determine that there is either a disconnection at the first point of connection 121 or the second point of connection 161, or the electrical cable 130 is damaged and instruct the ECU 120 to stop delivery of its DC voltages. In one example, a component of the ECU 120 monitors the DC power levels of the ECU 120. In another example, the DC power levels of the ECU 120 are monitored by a unit external to the ECU 120.

In one example, once the delivery has stopped, the first DSP 115 may load dump any residual voltages, for example, those found in the electrical cable 130 to a dump circuit (not shown). Examples of the clump circuit may include a relay switch coupled to a resistive load, a solid state switch coupled to a resistive load, etc. Although the examples disclose that the first DSP 115 instructs the delivery of AC voltages (to start, to continue and/or to stop delivery), one skilled in the art would understand that these examples are not limited to the first DSP 115 and that other DSPs (e.g. the second DSP 155) may be used without limiting the scope and spirit of the present disclosure.

Although the examples herein disclose that the ECU 120 delivers AC voltages to the inverter, there may be cases wherein the ECU 120 delivers DC voltages to the inverter 160 or to another electrical unit. Thus, one skilled in the art would understand that the present disclosure would include within its scope and spirit delivery and reception of either AC voltages or DC voltages.

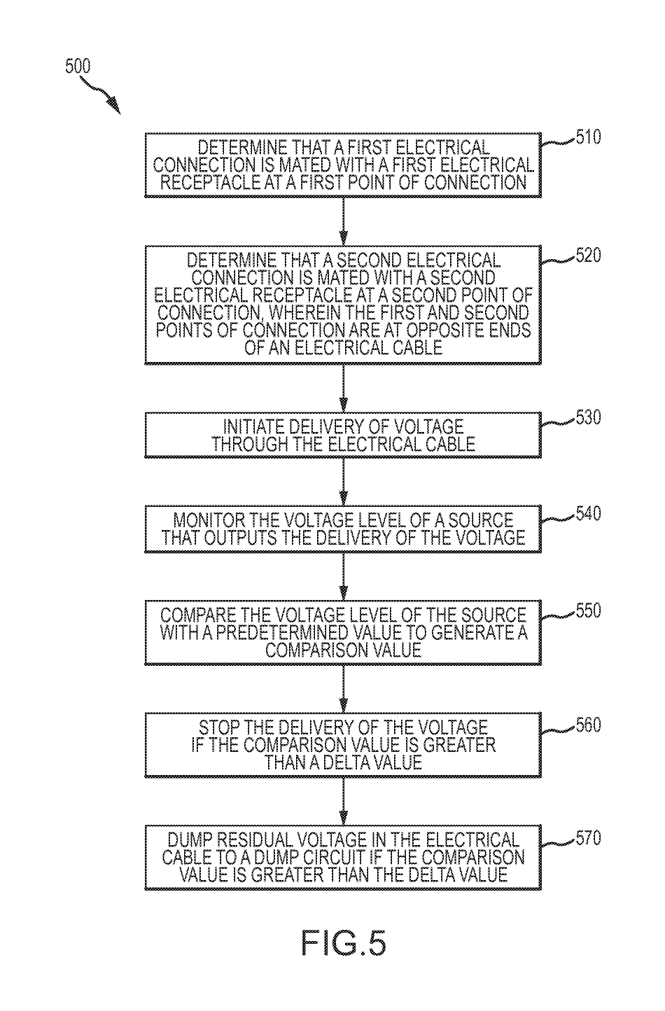

FIG. 5 illustrates an example flow diagram 500 for connecting electrical units. In block 510, determine that a first electrical connection is mated with a first electrical receptacle at a first point of connection. In one example, a first sensor determines that there is a mate. In block 520, determine that a second electrical connection is mated with a second electrical receptacle at a second point of connection, wherein the first and second points of connection are at opposite ends of an electrical cable. In one example, a second sensor determines that there is a mate. In one example, the first and second sensors are of the same type of sensor. In another example, the first sensor is of a type of sensor that is different from the second sensor. In block 530, initiate delivery of voltage through the electrical cable. In one example, the ECU initiates the delivery. However, one skilled in the art would understand that in some examples, other electrical units may initiate the delivery, for example, a processor such as the DSP 115). In one example, the voltage is DC voltage.

In block 540, monitor the voltage level of a source that outputs the delivery of the voltage. In cone example, a processor (such as the DSP 115) performs the monitoring of the voltage. In one example, the source is an electrical control unit. In block 550, compare the voltage level of the source with a predetermined value to generate a comparison value. In one example, a processor (such as the DSP 115) compares the voltage level of the source with the predetermined value to generate the comparison value. In block 560, stop the delivery of the voltage if the comparison value is greater than a delta value. In one example, the delivery is stopped by the ECU. In another example, a processor (such as the DSP 115) causes the ECU to stop the delivery.

Following, block 560, in block 570, dump residual voltage in the electrical cable to a dump circuit if the comparison value is greater than the delta value. In another example, a processor (such as the DSP 115) initiates the dump. In one example, the first and second electrical connections and the first and second electrical receptacles are part of the electrical cable that electrically connects a tractor and a trailer. In one example, the ECU is housed in the tractor and an inverter is housed in the trailer, and the inverter receives the voltage outputted by the ECU through the electrical cable. In one example, a refrigeration unit housed in the trailer, and the refrigeration unit receives alternating current (AC) voltages outputted by the inverter.

One skilled in the art would understand that the steps disclosed in the example flow diagram in FIG. 5 can be interchanged in their order without departing from the scope and spirit of the present disclosure. Also, one skilled in the art would understand that the steps illustrated, in the flow diagram are not exclusive and other steps may be included or one or more of the steps in the example flow diagram may be deleted without affecting the scope and spirit of the present disclosure.

Those of skill would further appreciate that the various illustrative components, logical blocks, modules, circuits, and/or algorithm steps described in connection with the examples disclosed herein may be implemented as electronic hardware, firmware, computer software, or combinations thereof. To clearly illustrate this interchangeability of hardware, firmware and software, various illustrative components, blocks, modules, circuits, and/or algorithm steps have been described above generally in terms of their functionality. Whether such functionality is implemented as hardware, firmware or software depends upon the particular application and design constraints imposed on the overall system. Skilled artisans may implement the described functionality in varying ways for each particular application, but such implementation decisions should not be interpreted as causing a departure from the scope or spirit of the present disclosure.

For example, for a hardware implementation, the processing units may be implemented within one or more application specific integrated circuits (ASICs), digital signal processors (DSPs), digital signal processing devices (DSPDs), programmable logic devices (PLDs)) field programmable gate arrays (FPGAs), processors, controllers, micro-controllers, microprocessors, other electronic units designed to perform the functions described therein, or a combination thereof. With software, the implementation may be through modules (e.g., procedures, functions, etc.) that perform the functions described therein. The software codes may be stored in memory units and executed by a processor unit. Additionally, the various illustrative flow diagrams, logical blocks, modules and/or algorithm steps described herein may also be coded as computer-readable instructions carried on any computer-readable medium known in the art or implemented in any computer program product known in the art. In one aspect, the computer-readable medium includes non-transitory computer-readable medium.

In one or more examples, the steps or functions described herein may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media may include RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrareds radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

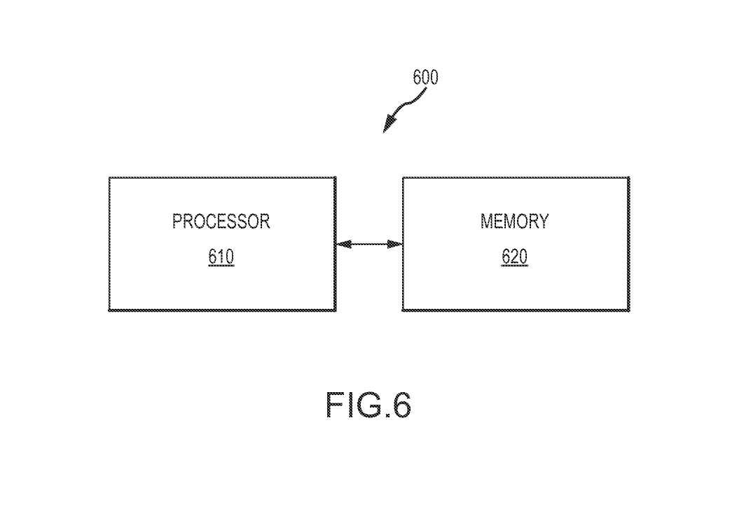

In one example, the illustrative components, flow diagrams, logical blocks, modules and/or algorithm steps described herein are implemented or performed with one or more processors. In one aspect, a processor is coupled with a memory which stores data, metadata, program instructions, etc. to be executed by the processor for implementing or performing the various flow diagrams, logical blocks and/or modules described herein. FIG. 6 illustrates an example of a device 600 comprising a processor 610 in communication with a memory 620 for executing connecting electrical units. In one example, the device 600 is used to implement the algorithm illustrated in FIG. 5. In one aspect, the memory 620 is located within the processor 610. In another aspect, the memory 620 is external to the processor 610. In one aspect, the processor includes circuitry for implementing or performing the various flow diagrams, logical blocks and/or modules described herein.

The previous description of the disclosed aspects is provided to enable any person skilled in the art to make or use the present disclosure. Various modifications to these aspects will be readily apparent to those skilled in the art, and the generic principles defined herein may be applied to other aspects without departing from the spirit or scope of the disclosure.

1. A method for connecting electrical units, comprising:
determining that a first electrical connection is mated with a first electrical receptacle at a first point of connection;
determining that a second electrical connection is mated with a second electrical receptacle at a second point of connection, wherein the first second point of connection and the second point of connection are at opposite ends of an electrical cable;
initiating delivery of voltage through the electrical cable;
monitoring the voltage level of it source that outputs the delivery of the voltage; and
comparing the voltage level of the source with a predetermined value to generate a comparison value.

2. The method of claim 1 further comprising stopping the delivery of the voltage if the comparison value is greater than a delta value.

3. The method of claim 2 further comprising dumping residual voltage in the electrical cable to a dump circuit if the comparison value is greater than the delta value.

4. The method of claim 1, wherein the determining steps are based on at least one measurement value from a sensor.

5. The method of claim 4 wherein the sensor is one of the following: a proximity sensor, a magnetic sensor, an electromagnetic sensor, an optoelectronic sensor, an infrared sensor, a radio frequency (RF) sensor, or a piezoelectric sensor.

6. The method of claim 1 further comprising connecting a first end of the electrical cable to a first electrical unit in a tractor, and connecting a second end of the electrical cable to a second electrical unit in a trailer.

7. The method of claim 6, wherein the first electrical unit is an electrical control unit and the second electrical unit is an inverter.

8. The method of claim 7, wherein the voltage is a direct current (DC) voltage.

9. A device comprising a processor and a memory, the memory containing program code executable by the processor for performing the following:
determining that a first electrical connection is mated with a first electrical receptacle at a first point of connection;
determining that a second electrical connection is mated with a second electrical receptacle it a second point of connection, wherein the first second point of connection and the second point of connection are at opposite ends of an electrical cable;
initiating delivery of voltage through the electrical cable;
monitoring the voltage level of a source that outputs the delivery of the voltage; and
comparing the voltage level of the source with a predetermined value to generate a comparison value.

10. The device of claim 9, wherein the memory further comprising program code for stopping the delivery of the voltage if the comparison value is greater than a delta value.

11. The device of claim 10, wherein the memory further comprising program code for dumping residual voltage in the electrical cable to a dump circuit if the comparison value is greater than the delta value.

12. The device of claim 9, wherein at least one measurement value from a sensor is used for determining that the first electrical connection is mated with the first electrical receptacle at the first point of connection.

13. The device of claim 12, wherein at least one other measurement value from the sensor is used for determining that the second electrical connection is mated with the second electrical receptacle at the second point of connection.

14. A computer program product embodied on a non-transitory computer-readable storage medium and comprising code that, when executed, causes a computer to perform the following:
determining that a first electrical connection is mated with a first electrical receptacle at a first point of connection;
determining that a second electrical connection is mated with a second electrical receptacle at a second point of connection, wherein the first second point of connection and the second point of connection are at opposite ends of an electrical cable;
initiating delivery of voltage through the electrical cable;
monitoring the voltage level of a. source that outputs the delivery of the voltage; and
comparing the voltage level of the source with a predetermined value to generate a comparison value.

15. The computer program product of claim 14 wherein execution of the code is also for stopping the delivery of the voltage if the comparison value is greater than a delta value.

16. The computer program product of claim 15 wherein execution of the code is also for dumping residual voltage in the electrical cable to a dump circuit if the comparison value is greater than the delta value.

17. A system for connecting electrical units, comprising:
a first sensor for determining that a first electrical connection is mated with a first electrical receptacle at a first point of connection
a second sensor for determining that a second electrical connection is mated with a second electrical receptacle at a second point of connection, wherein the first second point of connection and the second point of connection are at opposite ends of an electrical cable;
an electrical control unit (ECU) for initiating delivery of voltage through the electrical cable based on a first measurement from the first sensor and a second measurement form the second sensor; and
a digital signal processor (DSP) coupled to the ECU for monitoring the voltage level of a source that outputs the delivery of the voltage, and for comparing the voltage level of the source with a predetermined value to generate a comparison value.

18. The system of claim 17, wherein the ECU stops the delivery of the voltage if the comparison value is greater than a delta value.

19. The system of claim 18, wherein the digital signal processor (DSP) initiates dumping residual voltage in the electrical cable to a dump circuit if the comparison value is greater than the delta value.

20. The system of claim 19 wherein the dump circuit is one of the following: a relay switch coupled to a resistive load, or a solid state switch coupled to a resistive load.

21. The system of claim 17, wherein the first and second electrical connections and the first and second electrical receptacles are part of an electrical cable that electrically connects a tractor and a trailer.

22. The system of claim 21, wherein the ECU is housed in the tractor and an inverter is housed in the trailer, and wherein the inverter receives the voltage outputted by the ECU thru the electrical cable.

23. The system of claim 22 further comprising a refrigeration unit housed in the trailer, wherein the refrigeration unit receives alternating current (AC) voltages outputted by the inverter.
